(19) United States
(12) Patent Application Publication
(10) Pub. No.: US 2015/0293162 A1
(43) Pub. Date: Oct. 15, 2015

(54) ELECTROMAGNETIC FIELD FEATURE CLASSIFICATION AND PRESENTATION DEVICE

(71) Applicant: NEC CORPORATION, Tokyo (JP)

(72) Inventors: Kenta Tsukamoto, Tokyo (JP); Manabu Kusumoto, Tokyo (JP); Hiroshi Toyao, Tokyo (JP)

(73) Assignee: NEC CORPORATION, Tokyo (JP)

(21) Appl. No.: 14/438,126

(22) PCT Filed: Sep. 4, 2013
(86) PCT No.: PCT/JP2013/074447

§ 371 Date: Apr. 23, 2015

(30) Foreign Application Priority Data
Oct. 24, 2012 (JP) 2012-234641

(51) Int. Cl. G01R 29/08

(52) U.S. Cl. CPC G01R 29/0892; G01R 29/0871; G01R 29/0878

(57) ABSTRACT

An electromagnetic field feature classification and presentation device is provided with: an acquisition means for collecting time series measurement data relating to an electromagnetic wave emitted from an object to be measured while associating the measurement data with the coordinates of positions; a feature amount calculation means for calculating one or more feature amounts for the coordinates of each position regarding the measurement data collected by the acquisition means; a feature analysis means for performing feature classification based on a cluster analysis on feature amount groups in the coordinates of respective positions calculated by the feature amount calculation means; a mapping processing means for linking classification results by the feature analysis means with the coordinates of respective positions and mapping the classification results on a space corresponding to the object to be measured; and an output means for presenting the result of the mapping by the mapping processing means.

### TECHNICAL FIELD

The present invention relates to an electromagnetic wave measurement system, and more particularly to an electromagnetic field feature classification and presentation device, an electromagnetic near-field distribution measurement system, an electromagnetic field feature classification program and an electromagnetic field feature classification method that may be used for collecting time series electromagnetic wave data emitted from an object to be measured and identifying a noise source and a noise propagation path of an electromagnetic interference wave.

### BACKGROUND ART

In the design and development of a circuit board on which electronic components are mounted, wireless communication failure or malfunction of electronic devices due to an electromagnetic interference wave (EMI: Electric Magnetic Interference) has become a problem. In the design and development of recent years, in order to identify a generation source of an electromagnetic wave causing such electromagnetic wave interference, the electromagnetic near-field measurement has been performed. The electromagnetic near-field measurement is a technique to scan a near-field on a circuit board by use of an electromagnetic field probe and detect a point with a high noise intensity by successively acquiring frequency responses in the electromagnetic field at each measurement point. Electromagnetic performance measurement of a circuit board and a product is also performed by a similar method.

For such a technology field, many technologies to identify a noise source more efficiently have been disclosed.

In PTL1, a method to measure an electric field component and a magnetic field component of an electromagnetic field in the vicinity of a circuit board by bringing a loop antenna close to the vicinity of the circuit board and measuring a composite current composed of a current generated by the electric field and a current generated by the magnetic field is proposed.

In PTL2, an apparatus that makes it possible to identify a noise source by displaying a distribution chart of electromagnetic field intensity from an electromagnetic wave emitted from a circuit board and image data of the circuit board in a superposed manner on a display is proposed.

In PTL3, an apparatus that acquires information on a noise significantly influencing a transmission and reception function of an electronic device by evaluating a correlation between an electromagnetic field distribution around an antenna and an electromagnetic field distribution of an interference wave in the vicinity of a circuit board is proposed. In PTL3, a related technology to measure a distribution of an electromagnetic field of an electronic device and identify a generation source of the electromagnetic field is also disclosed.

In PTL4, a technology to carry out a measurement at a plurality of measurement points for a predetermined duration in order to take into consideration a temporal variation of a noise in measuring the noise produced from an object to be measured with a probe, create data on an intensity variation with respect to each measurement point, and generate an intensity distribution of the noise is described.

### CITATION LIST

### Patent Literature

PTL1: Japanese Unexamined Patent Application Publication No. 2000-206163
PTL2: Japanese Unexamined Patent Application Publication No. 2000-019204
PTL3: Japanese Unexamined Patent Application Publication No. 2007-192744
PTL4: Japanese Unexamined Patent Application Publication No. 2011-017718

### SUMMARY OF INVENTION

### Technical Problem

With the advancement of electronic devices, requirements for EMI countermeasures and performance measurements have become complicated. Thus, users of the EMI countermeasures and performance measurements have spent a great deal of efforts and time for each object to be measured every day. For example, in recent multi-functional wireless communication terminals, because LSIs are mounted in high density on the same circuit board and have come to work at a low operating voltage, influence of a noise on functional failures is in a tendency to increase more than ever, and the EMI countermeasures have become further complicated. Measures for improving performance and adjusting directional characteristics of antennas have also become complicated.

The technologies described in PTL1 and PTL2 focus on only the intensity of a noise on a circuit board, and a degree of coupling of a noise with a transmission and reception unit and other circuits, which are interfered portions, is not considered. Although the intensity of a noise is low, influence on functional failures has a significant impact when the coupling of the noise is strong, using an evaluation index in which an actual degree of coupling is incorporated is required.

The technology described in PTL3, by evaluating a correlation between an electromagnetic field distribution on an antenna and an electromagnetic field distribution on a circuit board, extracts a noise source with a high degree of coupling with an interfered portion.

The technology described in PTL4 is capable of creating and presenting an intensity distribution chart in which a temporal variation at the coordinates of each of multiple measurement points is incorporated.

However, a noise source with high noise intensity does not always become a principal cause for a communication failure and a malfunction. In an actual case in which influence on a communication failure is incorporated, occurrence frequency, phase information, or the like of a noise sometimes becomes a significantly important parameter. In consequence, there is a problem such that decision based on only an intensity distribution is not sufficient to evaluate a degree of influence on functional failures.

In the current EMI countermeasures, due to a lot of reasons including the above-described reason, while referring to an intensity distribution obtained in EMI evaluation, a noise source is determined based on experience and knowledge of a measurer, and countermeasures against it is taken.

The present invention is made in consideration of the above-described problems, and an object of the present invention is to provide an electromagnetic field feature classification and presentation device that includes an electromagnetic wave classification and presentation function capable of feature classification of electromagnetic waves emitted from an object to be measured.

Another object of the present invention is to provide an electromagnetic near-field distribution measurement system for an electromagnetic near field that includes an electromagnetic wave classification and presentation function capable of feature classification of electromagnetic waves emitted from an object to be measured.

### Solution to Problem

An electromagnetic field feature classification and presentation device according to the present invention includes: an acquisition means for collecting time series measurement data on an electromagnetic wave emitted from an object to be measured in association with each coordinate of position; a feature amount calculation means for calculating one or a plurality of feature amounts for each coordinate of position with respect to the measurement data collected by the acquisition means; a feature analysis means for performing feature classification based on a cluster analysis for a group of the feature amounts calculated by the feature amount calculation means at each coordinate of position; a mapping processing means for associating a classification result by the feature analysis means with the coordinate of position and maps the classification result on a space corresponding to the object to be measured by applying the number of feature classifications; and an output means for presenting a result of mapping by the mapping processing means.

An electromagnetic near-field distribution measurement system according to the present invention includes; probe that senses an electromagnetic near field; a probe scanning means for scanning the probe;

a control means for controlling the probe scanning means in synchronization with measurement of an electromagnetic wave; an acquisition means for collecting time series measurement data on an electromagnetic wave emitted from an object to be measured via the probe in association with each coordinate of position; a feature amount calculation means for calculating one or a plurality of feature amounts for each coordinate of position with respect to the measurement data collected by the acquisition means; a feature analysis means for performing feature classification based on a cluster analysis for a group of feature the amounts calculated by the feature amount calculation means at each coordinate of position; a mapping processing means for associating a classification result by the feature analysis means with the coordinate of position and maps the classification result on a space corresponding to the object to be measured by applying the number of feature classifications; and an output means for presenting a result of mapping by the mapping processing means.

An electromagnetic field feature classification program according to the present invention causes a control unit of an information processing system to function as: an acquisition means for collecting time series measurement data on an electromagnetic wave emitted from an object to be measured in association with each coordinate of position; a feature amount calculation means for calculating one or a plurality of feature amounts for each coordinate of position with respect to the measurement data collected by the acquisition means; a feature analysis means for performing feature classification based on a cluster analysis for a group of the feature amounts calculated by the feature amount calculation means at each coordinate of position; and a mapping processing means for associating a classification result by the feature analysis means with the coordinates of positions and maps the classification result on a space corresponding to the object to be measured by reflecting the number of feature classifications.

An electromagnetic field feature classification method according to the present invention includes: collecting time series measurement data on an electromagnetic wave emitted from an object to be measured in association with each coordinate of position; calculating one or a plurality of feature amounts for each coordinate of position with respect to the collected measurement data; performing feature classification processing based on a cluster analysis for a group of the calculated feature amounts at the each coordinate of position; and associating a classification result by the feature classification processing with the coordinates of positions and mapping the classification results on a space corresponding to the object to be measured by reflecting the number of feature classifications.

### Advantageous Effects of Invention

According to the present invention, it is possible to provide an electromagnetic field feature classification and presentation device that includes an electromagnetic wave classification and presentation function capable of feature classification of electromagnetic waves emitted from an object to be measured.

According to the present invention, it is possible to provide an electromagnetic near-field distribution measurement system for an electromagnetic near field that includes an electromagnetic wave feature classification and presentation function capable of feature classification of electromagnetic waves emitted from an object to be measured.

### BRIEF DESCRIPTION OF DRAWINGS

FIG. 1 is a block diagram illustrating a configuration of an electromagnetic field feature classification and presentation device according to the present invention;

FIG. 2 is a block diagram illustrating an electromagnetic near-field distribution measurement system according to the present invention;

FIG. 3 is an explanatory diagram illustrating an example of an object to be measured 1 used in exemplary embodiments;

FIG. 4A is an explanatory diagram illustrating an example of feature amounts (amplitude probability distribution and crossing rate distribution) measured at the coordinates of different positions on the object to be measured 1;

FIG. 4B is an explanatory diagram illustrating an example of feature amounts (amplitude probability distribution and crossing rate distribution) measured at the coordinates of different positions on the object to be measured 1;

FIG. 5 is a flowchart illustrating an example of processing operations in a feature analysis unit;

FIG. 6 is an explanatory diagram exemplifying a result when cluster analysis is carried out for features of measurement data groups;

FIG. 7 is a flowchart illustrating an example of processing operations in a mapping processing unit;

FIG. 8 is an explanatory diagram exemplifying a presentation method of a mapping result relating to functional feature classification;

FIG. 9 is an explanatory diagram exemplifying a presentation method of a mapping result relating to intensity classification;

FIG. 10 is an explanatory diagram describing an example of processing operations to determine a presentation method from a cluster analysis result;

FIG. 11 is an explanatory diagram exemplifying a result when cluster analysis is carried out for both features of measurement data groups and training data to which an index is assigned;

FIG. 12 is an explanatory diagram exemplifying a presentation method for the cluster analysis result illustrated in FIG. 11;

FIG. 13 is an explanatory diagram exemplifying a presentation method for a mapping result with design data; and

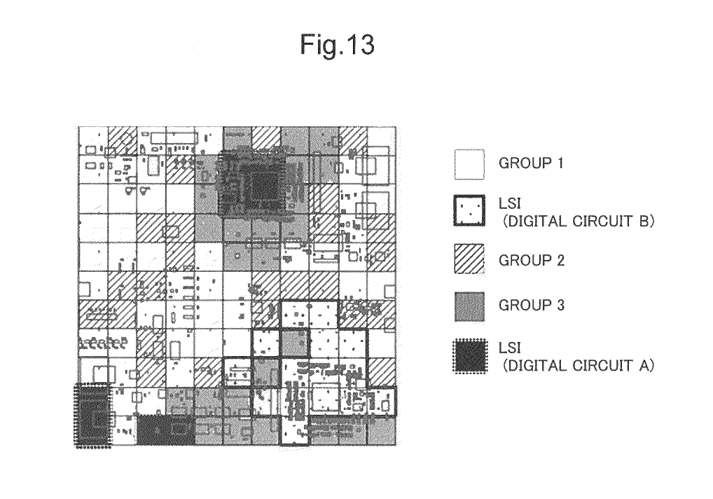

FIG. 14 is an explanatory diagram exemplifying a presentation method for a mapping result in which measurements in a plurality of measurement directions are incorporated.

### DESCRIPTION OF EMBODIMENTS

### First Exemplary Embodiment

An electromagnetic field feature classification and presentation device that is suitable for an electromagnetic near-field distribution measurement system which has a function to classify and display features of an electromagnetic wave will be described below as a first exemplary embodiment of the present invention.

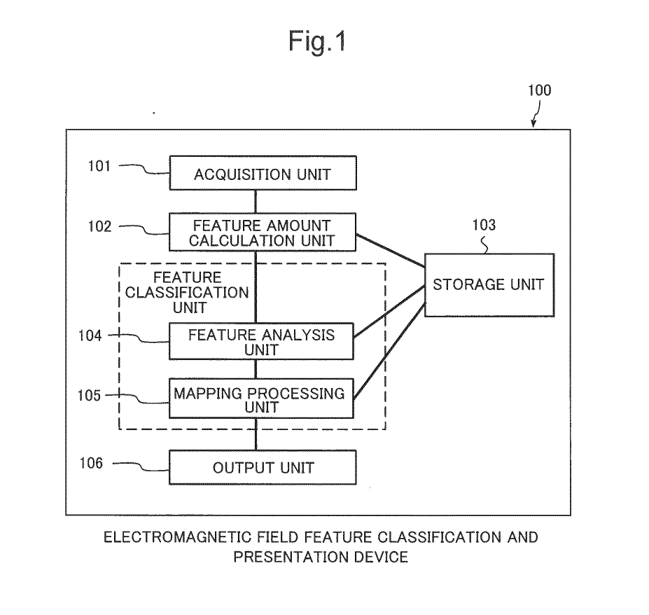

FIG. 1 is a block diagram illustrating a configuration of the electromagnetic field feature classification and presentation device. The electromagnetic field feature classification and presentation device 100 includes an acquisition unit 101, a feature amount calculation unit 102, a storage unit 103, a feature analysis unit 104, a mapping processing unit 105, and an output unit 106.

The acquisition unit 101 in FIG. 1 converts an electromagnetic wave including disturbance, such as an interference wave, into data. A voltmeter, an electric field strength meter, a spectrum analyzer, and so on that are capable of measuring amplitude for each frequency of the electromagnetic wave may be used as a reception interface in the acquisition.

The acquisition unit 101 has a function to repeat sampling (measurement of frequency values and amplitude values) with respect to each measurement point for a predetermined duration, and converts a waveform change over time of an electromagnetic wave into digital time series measurement data. The time series measurement data are associated with position coordinates information with respect to the coordinates of each position where the measurement is carried out.

The measurement data measured as described above are transmitted to the feature amount calculation unit 102 in a distinguishable manner with respect to the coordinates of each position.

The feature amount calculation unit 102 calculates one or a plurality of feature amounts from the time series measurement data sampled with respect to each measurement point. Since very high-speed sampling is carried out in order to sample time series data with significant temporal variation, such as an electromagnetic interference wave, with good precision, applying an analysis, which will be described later, straight to the measurement data causes an increase in processing load. Moreover, measuring instruments are required to have a large capacity memory.

By converting measurement data at each measurement point to one or a plurality of feature amounts, it is possible to compress data amount and to perform almost real time processing with a smaller resource. Classifications of the feature and the number of the classifications amounts may be arbitrarily determined.

As a feature amount, for example, a statistical parameter, such as amplitude probability distribution (APD) and crossing rate distribution (CRD), may be used in electromagnetic wave feature classification.

Although the following description will be made by using the amplitude probability distribution and the crossing rate distribution as an example of the feature amount, a single parameter, such as a mean value and a peak-to-peak value, or a single type of feature amount or a combination of a plurality of types of feature amounts among different types of feature amounts, such as amplitude probability density distribution, crossing rate distribution, pulse width distribution, and waiting time distribution, may be used.

When a combination of feature amounts is used, it is preferable to combine feature amounts indicating different types of information, such as amplitude and phase, to increase accuracy of classification. In the stipulated EMI countermeasures or the like, it is possible to measure the similarity of measurement data more accurately by combining a plurality of similar feature amounts.

The amplitude probability distribution (APD) is a statistic that is calculated as a ratio of a time Tᵢ during which an amplitude envelope is greater than a predetermined amplitude value Eₖ to a total measurement time T based on the time series measurement data of amplitude values, which are transmitted from the acquisition unit 101 at the preceding stage (see the formula (1) shown below). Since a relation between an occurrence frequency and an amplitude intensity of a noise is represented by the amplitude probability distribution, the amplitude probability distribution is useful as an interference wave evaluation scale for a digital noise.

$$APD ( {E}_{k} ) = \frac{{\sum }_{i = 1}^{h} {T}_{i} ( {E}_{k} )}{T} \qquad ( 1 )$$

The crossing rate distribution (CRD) is a statistic that is calculated as a ratio of the number of times Nᵢ when an amplitude envelope crosses a predetermined amplitude value Eₖ in the positive direction (or in the negative direction) to a total measurement time T (see the formula (2) shown below). A relation between the number of amplitude changes and an amplitude intensity of a noise is represented. When there is no overlap between pulses, the crossing rate distribution provides the number of pulses per unit time that have amplitude values surpassing the amplitude value Eₖ.

$$CRD ( {E}_{k} ) = \frac{{N}_{i} ( {E}_{k} )}{T} \qquad ( 2 )$$

The feature amount with respect to the coordinates of each position calculated by the feature amount calculation unit 102 is stored in the storage unit 103 in association with the measurement data.

When feature amount data for the required number of the coordinates of positions are acquired, the feature analysis unit 104 appropriately reads out a group of feature amounts of the same feature type at the coordinates of respective positions, which are stored in the storage unit 103, and carries out feature classification by applying cluster analysis. The cluster analysis is a machine learning method that compares degrees of similarity between pieces of data and forms a cluster with respect to each group of similar data.

By using the cluster analysis, it is possible to perform a feature classification to classify feature amount data at the coordinates of respective positions into data groups each of which has a high degree of similarity. The feature analysis unit 104 stores a result of the classification in the storage unit 103 after finishing the feature classification.

The mapping processing unit 105 reads out the classification results of the above-described cluster analysis with the coordinates of positions (measurement positions) from the storage unit 103, and sequentially maps the feature classification results in accordance with the predetermined or arbitrary number of partitions (the number of mapping classifications, that is: the number of feature classifications) to the coordinates of respective positions on a space corresponding to the object to be measured. With this mapping processing, it is possible to distinguish clusters, which are classified in accordance with features, from one another in a perceptible manner (for example, into group 1, group 2, and so on).

In the determination of the number of classified clusters (the number of mapping classifications, that is, the number of feature classifications), it is preferable for a user to be able to confirm a result of the cluster analysis and then determine the number by inputting a desirable value for the number of classifications from an external input terminal. It goes without saying that it is also possible to use a fixed value for the number of classified clusters. It may be possible that a plurality of the numbers of classifications is received from the user and succeeding processing is carried out in parallel. It may also be possible that an appropriate value for the number of partitions (the number of classification candidates) is proposed to the user from the device side and a value for the number of partitions responded by the user is employed by the device side. If a plurality of maps using the different numbers of classifications is presented in a comparable manner, it becomes possible to use information acquired through the measurement effectively.

Based on the number of classifications, the mapping processing unit 105 determines the number of colors, patterns, and/or the like corresponding to respective clusters, informs an output unit of the mapping results, and stores the mapping results in the storage unit.

The output unit 106 outputs the above-described mapping results by the mapping processing unit 105 on an external display device, such as a display.

With this presentation, the user is able to obtain an electromagnetic wave distribution image classified by feature and use the image for an EMI countermeasure or the like. This resembling feature distribution image may provide a convenience different from the one provided by an intensity distribution image which uses amplitude or the like in a predetermined frequency band.

### Example

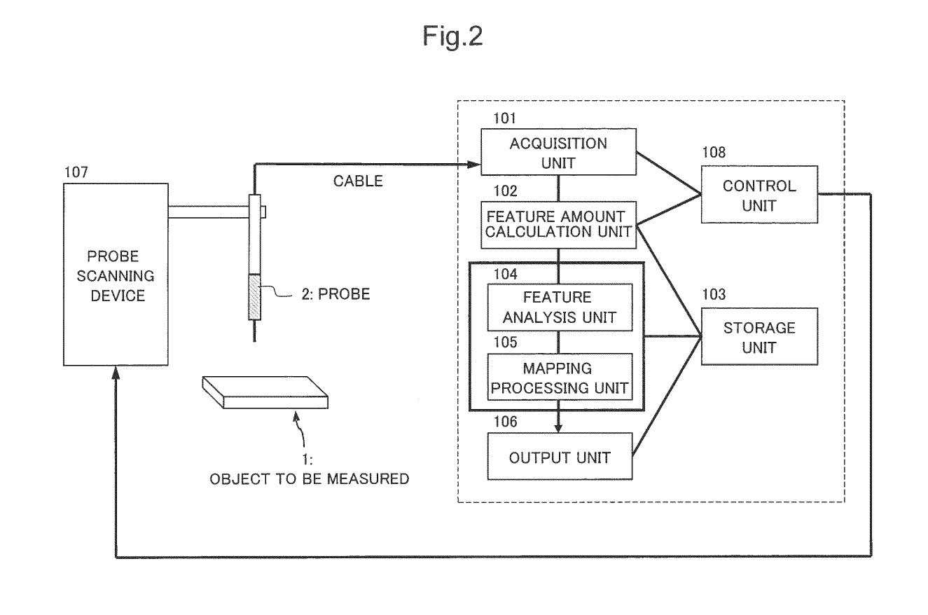

An example of the electromagnetic field feature classification and presentation device will be described below. FIG. 2 is a block diagram illustrating an example in which an electromagnetic field classification device 100 is incorporated in an electromagnetic near-field distribution measurement system. Description of details, such as an interface circuit, will be omitted.

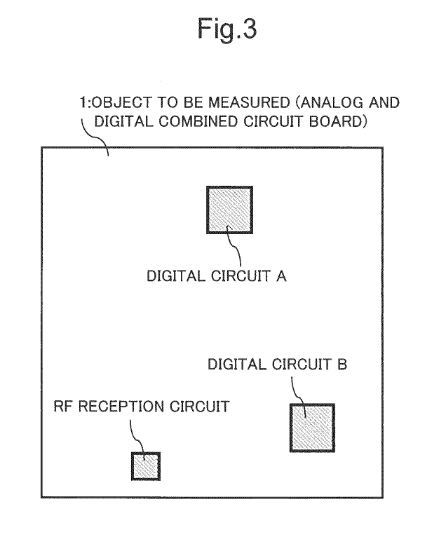

An object to be measured 1 is, for example, a circuit board of an electronic device. In this example, description will be made by using a wireless communication circuit board illustrated in FIG. 3 as an example. On the wireless communication circuit board, two LSIs (digital circuits A and B) and an RF reception circuit are mounted.

A probe 2 is a sensor that measures an electromagnetic field emitted from the object to be measured 1 in the vicinity of the object to be measured 1. The probe 2 is configured with a loop antenna, a dipole antenna, or the like to measure an electromagnetic field. The electromagnetic wave sensed by the probe 2 is input to the acquisition unit 101 via a cable.

A probe scanning device 107 maneuvers the electromagnetic field probe 2 to measure an electromagnetic field and a stage to scan the electromagnetic field probe 2. The object to be measured 1 is placed on the stage. It is preferable that the probe scanning device 107 is configured to be movable along three axes running up and down, back and forth, and right and left in order to move the electromagnetic field probe 2 to a position set by a control unit 108. A mechanism to reverse the circuit board to be measured upside down during a measurement may be built in. The probe scanning device 107 may be equipped with a mechanism having a range of motion that enables the probe 2 to cover both surfaces.

When an electromagnetic wave measurement is started, the control unit 108, by controlling the probe scanning device 107 based on an input measurement point information (scanning range), makes the electromagnetic field probe 2 move to a measurement start position. Then, the control unit 108 outputs a measurement start signal, which starts measurement of time series electromagnetic waves acquirable from the electromagnetic field probe 2 or a measurement condition to the acquisition unit 101 or the like. The control unit 108 may control the movement of the object to be measured 1 in coordination with the measurement of electromagnetic waves.

When the acquisition unit 101 receives the measurement start signal, the acquisition unit 101 starts measurement in accordance with the measurement condition, samples a measured frequency for a predetermined measurement time to convert the waveforms of electromagnetic waves into data with respect to each measurement position (measurement coordinates) included in the measurement condition, and acquires time series measurement data. The measurement data are appropriately transmitted to the feature amount calculation unit 102, which calculates specified feature amounts (amplitude probability distribution, crossing rate distribution, and so on). The calculated feature amount data are successively stored in the storage unit 103 in association with the coordinates of positions.

Feature amounts of the electromagnetic waves emitted from the object to be measured 1 will be described.

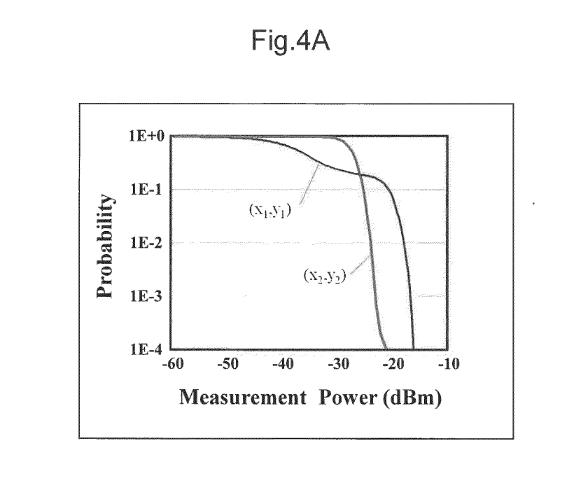

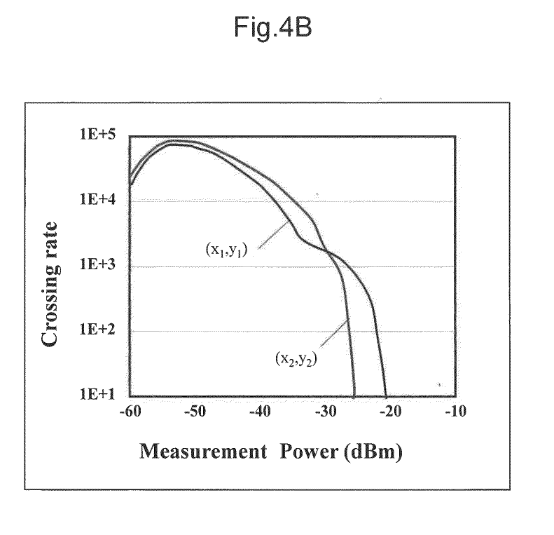

FIG. 4A illustrates an example of amplitude probability distributions acquired at the coordinates of different positions ((x1, y1) and (x2, y2)).

Two amplitude probability distributions exhibit distinctive curves individually and have slopes different from the slope of the amplitude probability distribution of a thermal noise. This indicates that there exist noises with different noise characteristics which originate from the two digital circuits.

FIG. 4B illustrates an example of crossing rate distributions acquired at the coordinates of different positions ((x1, y1) and (x2, y2)).

Because the crossing rate distribution represents the number of amplitude changes, the crossing rate distribution contains information that the amplitude probability distribution lacks.

By combining such a plurality of feature amounts containing different kinds of information, it is possible to improve accuracy in functional classification.

The control unit 108 decides whether or not all of the measurement coordinates of preset measurement points (measurement range) are covered, and, if not all of the measurement coordinates are covered, makes the electromagnetic field probe 2 move to a succeeding measurement point. When the control unit 108 has finished measuring all of the coordinates of measurement points by repeating sampling and measurement of the waveforms of the electromagnetic waves successively, the control unit 108 informs the probe scanning device 107 of the completion of probe movements and ends the acquisition of measurement data.

When storage of feature point data necessary to carry out a cluster analysis has been finished, electromagnetic wave classification processing is carried out by the feature analysis unit 104. Calculation of feature amounts and analysis, mapping processing, and display by using calculated feature amounts may be successively carried out in real time during the measurement of electromagnetic waves or the like. Redisplay or additional display may also be carried out by receiving the number of partitions, the types of feature amounts to be used, or the like from the user appropriately.

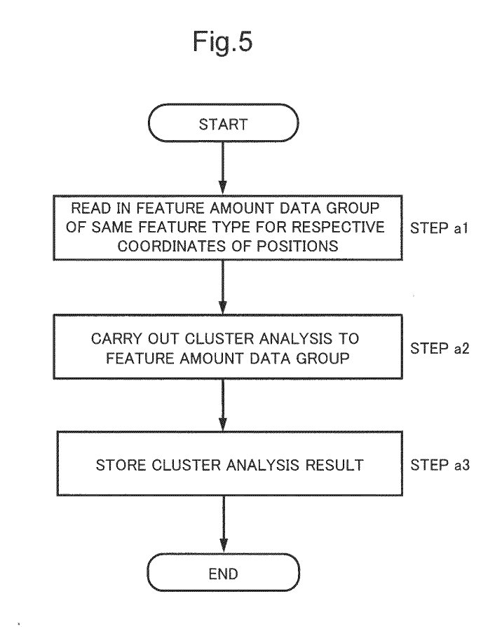

FIG. 5 is a flowchart illustrating an example of processing operations in the feature analysis unit 104. The feature analysis unit 104, when the number of pieces of feature amount data for the coordinates of respective positions, which are to be analyzed, has reached a required value, reads in feature amount groups for the coordinates of respective positions from the storage unit 103 (step a1). Next, the feature analysis unit 104 carries out cluster analysis for the read-in feature amount groups (step a2). When the cluster analysis has finished, the feature analysis unit 104 stores results of the analysis in the storage unit 103 (step a3).

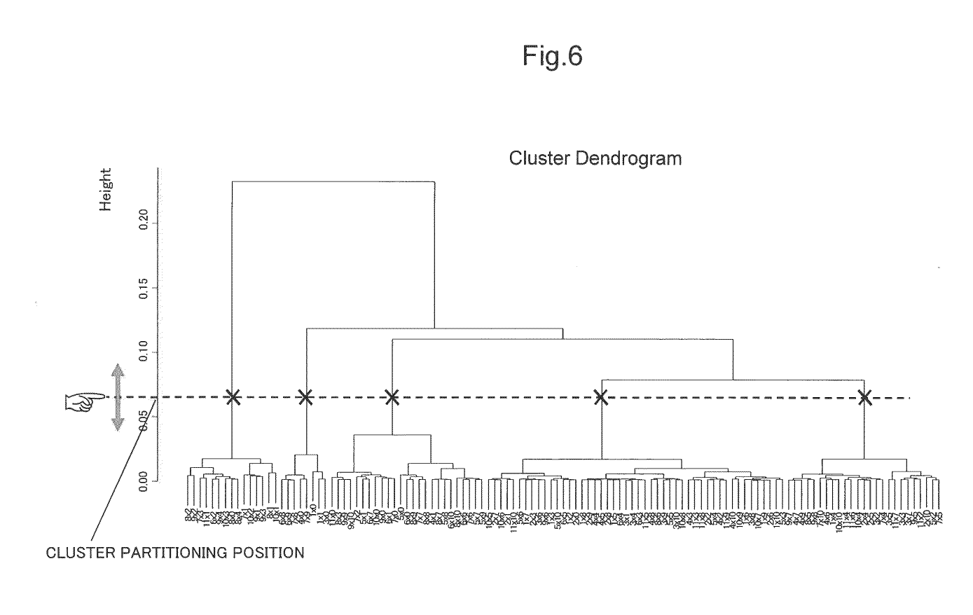

FIG. 6 is a cluster dendrogram illustrating results of applying hierarchical cluster analysis to features in the measurement data of the object to be measured 1. A cluster partitioning position is presented in a visually recognizable manner.

This hierarchical cluster analysis result is achieved by measuring an electromagnetic near field at grid points, which are specified by 11 points in the lateral direction and 11 points in the longitudinal direction (121 points in total), above the object to be measured 1 and applying hierarchical cluster analysis to amplitude probability distributions calculated as feature amounts.

In the analysis result, time series measurement data at the coordinates of respective measurement points are organized based on features acquired from waveforms. In other words, feature classification of the measurement data based on the cluster analysis has been carried out.

The hierarchical cluster analysis used in this example is a method of multivariate analysis in which, based on a definition of an inter-cluster distance, pieces of data with a high degree of similarity are merged into a cluster successively and the analysis ends when the whole data are merged into one cluster in the end.

In the hierarchical cluster analysis, as illustrated in FIG. 6, a distance (height, when assigned to the vertical axis) at which a cluster is formed is also acquired at the same time as clusters being formed.

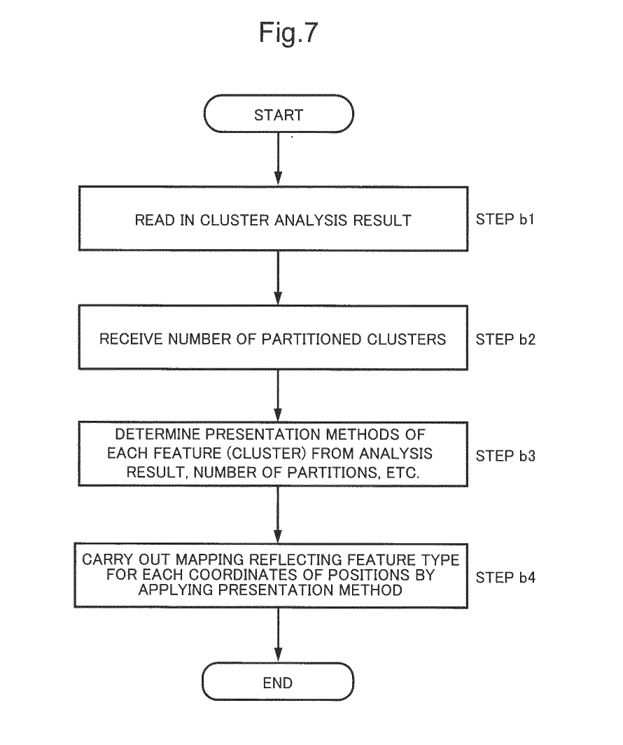

FIG. 7 is a flowchart illustrating an example of processing operations in the mapping processing unit 105.

The mapping processing unit 105 reads in the analysis result of the cluster analysis carried out by the preceding feature analysis unit 104 from the storage unit 103 (step b1). In this operation, the read-in cluster analysis result may be presented to the user from the succeeding output unit 106.

Next, a desirable partitioned number of clusters is received from the user (step b2). A predetermined value or a predetermined ratio based on the total number of analysis points (121 points in total) may be used initially. It is preferable that a choice of the value is appropriately received from the user afterward.

If the analysis result is a result of applying the hierarchical cluster analysis as a cluster analysis, the number of partitioned clusters is to be determined by the partitioning position (height) in the cluster dendrogram. When a value of 5 is received as the desirable value of the number of partitioned clusters, clusters are separated at the portion where branches are divided into five sub-branches as illustrated in the cluster dendrogram in FIG. 6.

This desirable partitioned number of clusters is used as the number of feature classifications (the number of classification groups, that is: the number of clusters) of a noise characteristic to which the user refers.

As described above, presenting an analysis result of the cluster analysis to the user in advance makes it possible to determine the number of partitioned clusters after confirming the analysis result, to find out excessive classification or vague classification in the cluster analysis based on knowledge, and to derive a better partitioned number of clusters.

Next, in accordance with the determined partitioned number of clusters, the mapping processing unit 105 assigns presentation methods, which will be used in presentation, to the coordinates of positions belonging to respective clusters after partitioning (step b3). For example, in receiving the determined value of 5 illustrated in FIG. 6, the mapping processing unit 105 assigns a different combination of a pattern and a color to each of the five groups.

Finally, the mapping processing unit 105 maps both the group classification result (feature classification result) and the presentation method (display color and pattern), in which the number of feature classifications is reflected, to the coordinates of respective positions on a two-dimensional plane (step b4).

The output unit 106 provides the user with a result of the mapping by the preceding mapping processing unit 105. As a provisioning method, any method, such as through a display or a printer, may be used. The mapping result may also be stored in the storage unit 103 to be used in other information processing.

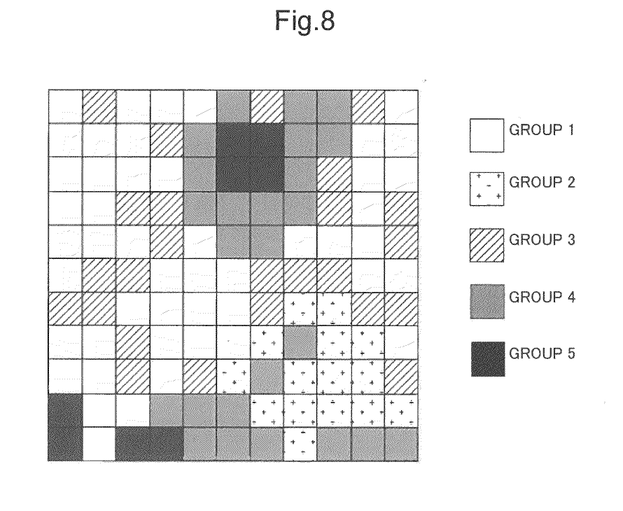

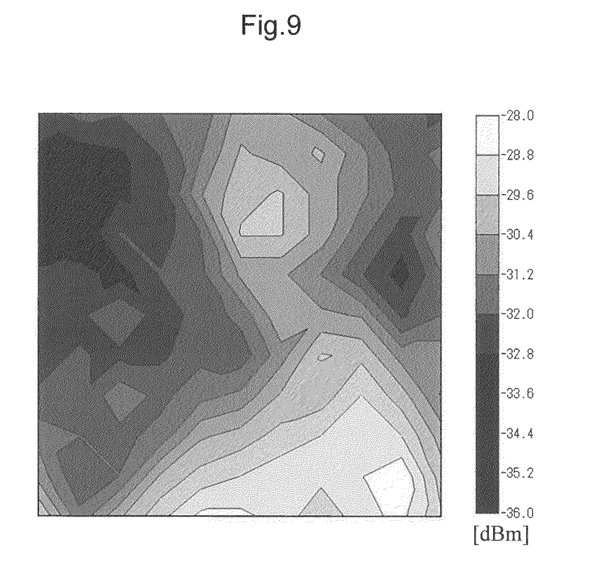

FIG. 8 illustrates a presentation example in a case of performing out feature classification to the measurement data by setting the number of clusters at 5. The intensity distribution of the measurement data corresponding to the case is illustrated in FIG. 9.

The user may obtain much information from the result illustrated in FIG. 8. First, based on the fact that different groups are formed in the vicinities of the coordinates of positions where two digital circuits (see FIG. 3) are mounted, it is possible to decide that the digital circuits A and B generate noises with different characteristics.

Next, when focusing on the vicinity of the coordinates of a position where the RF reception circuit is mounted, a portion that is classified in the same group as the digital circuit A, located in the upper portion, is visually recognizable. The result indicates a possibility that a noise which interferes with the RF reception circuit is caused by the digital circuit A, located in the upper portion. Based on this study, it is possible to suppose that the digital circuit A is a noise source that has a significant influence on a transmission and reception error.

In the decision described above, information that is difficult to read out from an intensity distribution, which maps points with a high noise intensity, is used. It is impossible to distinguish characteristics of two digital circuits from an intensity distribution of the electromagnetic wave from the object to be measured 1 illustrated in FIG. 9. The coordinates of a position where the RF reception circuit is mounted appear to be electromagnetically coupled to the digital circuit B which is close to the RF reception circuit, and it is thus difficult to carry out a correct decision based on only an intensity distribution of an electromagnetic wave.

The system is capable of distinguishing different noise components with respect to each feature and identifying similar noises. Therefore, it is possible to provide useful information to, for example, easily find out a noise source having a significant influence on an interfered portion. In addition, since the classification method is based on machine learning, it becomes possible to carry out an analysis that does not rely on experience and knowledge of a worker. If a plurality of different types of feature classification and cluster analysis are carried out for identical measurement data and feature classification results therefrom are compared, it becomes easier to obtain knowledge expected by the user.

For example, in wireless communication of recent years in which diversity technique, that performs transmission and reception by using a plurality of antennas, is employed, many antennas and peripheral circuits may be mounted on a wireless terminal to improve communication quality and diversify communication methods. For such a wireless terminal with a complex configuration, it may become necessary to apply EMI countermeasures to all antennas to be mounted. On the other hand, man-hours required for evaluation may increase. By using the method described in the first exemplary embodiment, it becomes possible to identify a noise source coupled to each antenna in a short time and apply a proper countermeasure.

### Second Exemplary Embodiment

As a second exemplary embodiment of the present invention, an electromagnetic field feature classification and presentation device, which is suitable for an electromagnetic near-field distribution measurement system having a function to classify and display features of an electromagnetic wave, will be described below.

The second exemplary embodiment has a configuration such that a presentation method for each cluster to be mapped is automatically selected based on distances between clusters acquired from a cluster analysis result in a mapping processing unit 105.

Operations from the start of measurement to the processing by a feature analysis unit 104 are the same as the first exemplary embodiment and thus description thereof will be omitted.

The mapping processing unit 105 reads in a cluster analysis result from a storage unit 103 and performs a selection of a presentation method to be assigned to each of partitioned clusters in receiving a specification of the number of partitions. In this processing, the mapping processing unit 105 determines, for example, a presentation color for mapping of each group based on inter-cluster distances acquired from the cluster analysis. The mapping processing unit 105 maps a feature classification result in accordance with a predetermined or arbitrary value of the number of partitions to the coordinates of respective positions on a space by incorporating the determined presentation method.

In a case of applying hierarchical cluster analysis as exemplified in FIG. 6, the height of a joint in a cluster dendrogram is expressed by an inter-cluster distance when clusters are merged. Therefore, by selecting presentation methods based on inter-cluster distances, it is possible to perform a mapping that expresses degrees of similarity between respective groups. In the selection, a degree of similarity between patterns (for example, density of dots or hatched lines) may be used. Clusters with short inter-cluster distances may be, more plainly, expressed by closeness between gradations of a color. A combination of these methods may also be employed.

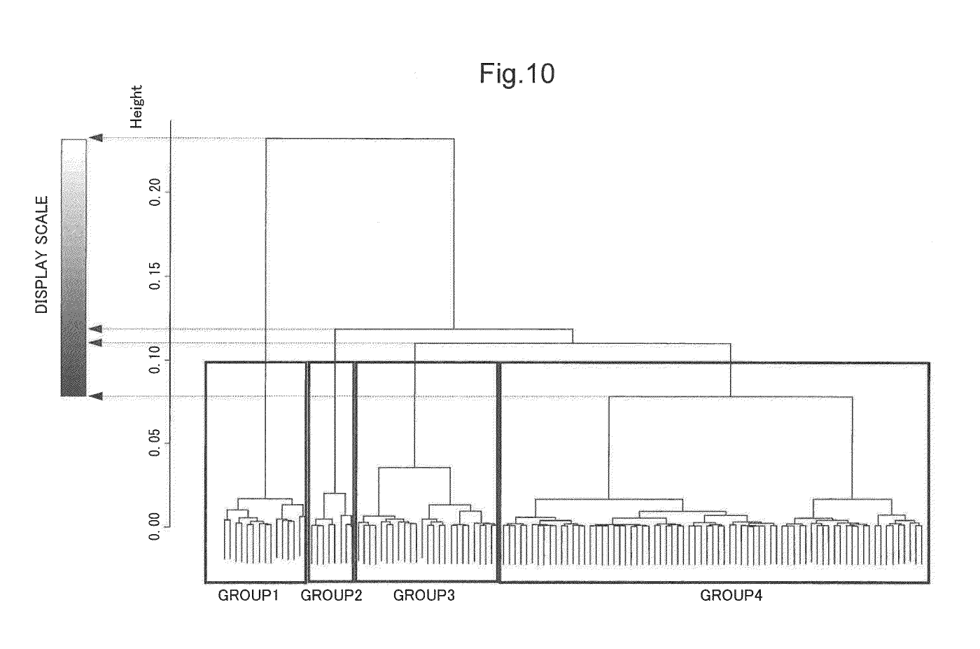

FIG. 10 is a schematic view illustrating an example of processing to determine display colors from inter-cluster distances when the clusters are partitioned into four groups. It may be possible that this schematic view is presented to the user and various operations are accepted.

The mapping processing unit 105 receives a value of 4 as the number of partitions, partitions the whole data into four clusters, and selects a display scale (display color) which expresses the distance at which each cluster is merged with another cluster based on a maximum distance when the whole is formed into a cluster.

More precisely, in the cluster dendrogram illustrated in FIG. 10, the number of groups is 4, and the mapping processing unit 105 determines a display color based on the height when all four clusters are merged into a cluster (arrow at the uppermost position) and the height at which each cluster is merged with another cluster.

As a result, a height at which the group 1 is merged and a height at which the group 4 is merged becomes a basis for the range from the minimum value to the maximum value of the display scale, and display colors are determined by the height at which the group 3 is merged and the height at which the group 2 is merged from the display scale.

As described above, in the hierarchical cluster analysis, it is possible to determine a display color of each group based on the height at which the group is merged with another group.

The height of a branch in a cluster dendrogram indicates a distance when clusters are merged. Therefore, it is possible to carry out a more distinctive classification when clusters have a sufficient height in cluster partitioning. For example, the cluster of the group 1 is distanced from other merged clusters, and thus it can be said that the group 1 is a group that has a significantly distinctive noise characteristic. On the other hand, because the distance between the cluster of the group 2 and the merged cluster from the groups 3 and 4 is not so high, it can be decided that these groups are noise components that are similar to each other to some extent.

For a color phase used for the scale of display colors, a generally used color phase, such as varying colors from red to blue, from white to black, or from white to red to blue to black, which express a distribution from the maximum value to the minimum value, may be used arbitrarily.

As described above, if the selection of presentation methods assigned to respective partitioned clusters is carried out by arithmetic processing based on an order or a ratio by use of inter-cluster distance values, it becomes possible to increase visibility further.

When the whole data resemble (when the scale width is small in the cluster dendrogram), or the like, inter-cluster distances may be accentuated by squaring the distances or the like.

Selecting a presentation method based on cluster distances has an advantageous effect that it becomes easier for a user to visually recognize similarities between cluster distances from a mapping result on a space. It is possible to suppose that groups with close color phases are components that are similar to each other to some extent.

### Third Exemplary Embodiment

As a third exemplary embodiment of the present invention, an electromagnetic field feature classification and presentation device which is suitable for an electromagnetic near-field distribution measurement system having a function to classify and display features of an electromagnetic wave will be described below.

The third exemplary embodiment has a configuration such that data of a characteristic noise, the generation of which is caused by a digital circuit device, a circuit configuration, or the like, are pre-stored and used as training data.

A mapping processing unit 105, with respect to a group into which training data are classified, provides a user with an index associated with the training data referring to a cluster analysis result. The mapping processing unit 105 also provides a function to stress the coordinates of measurement points that have characteristics resembling the training data in presenting a mapping result.

Operations from the measurement start to the processing by a feature amount calculation unit 102 are the same as the operations in the first exemplary embodiment, therefore description thereof will be omitted.

In the third exemplary embodiment, one or a plurality of sets of training data (sample), with which reference information (index) expected to be presented to the user in mapping is associated, are stored in a storage unit 103. The training data are, for example, feature amounts of characteristics of a noise emitted from an arbitrary digital circuit or device, a feature amount of an interfered portion, a feature amount of a thermal noise, or the like. A plurality of feature amounts may be contained in a set of training data.

As the training data, known information which has been acquired through an actual measurement may be used, and information which has been pre-calculated through simulation or theoretical calculation may be used.

A feature analysis unit 104 reads in feature amount group at the coordinates of respective positions and one or a plurality of sets of training data from the storage unit 103.

Next, the feature analysis unit 104 combines the feature amounts at the coordinates of respective positions with the training data and carries out a cluster analysis for the combined data. When the cluster analysis finishes, the feature analysis unit 104 stores an analysis result in the storage unit 103. The analysis result acquired in this processing is a cluster analysis result for data which have the training data incorporated in some groups. In other words, measurement data at the coordinates of positions which resemble the training data are classified by feature into the same group as the training data.

The mapping processing unit 105 reads in the feature classification result from the storage unit 103, receives a specification of the number of partitions, and selects presentation methods assigned to respective partitioned clusters. At this time, the mapping processing unit 105 recognizes a cluster containing the training data, and, with respect to the coordinates of positions of the cluster group, determines the presentation methods, by which the clusters are distinguishable as required by carrying out stressed display, assigning predetermined display colors or patterns, displaying the index associated with the training data, and/or the like. The mapping processing unit 105 maps the feature classification result in accordance with the predetermined or arbitrary value of the number of partitions to the coordinates of respective positions on a space by applying the determined presentation methods.

The index associated with the training data includes a cause and a countermeasure, related technologies, a device name, a development model name, or the like. It is also possible to associate circuit design data, a specification of a device, or the like with the training data. Other training data associated with features of the training data may also be associated. Associating training data with the analyzed data enables to switch stressed features (clusters, or groups) by selecting an index. A mechanism to activate an index depending on distances between groups or sub-groups into which training data are to be included may also be incorporated. For example, by making an index with predetermined wording presented in a case of the distance between the clusters including two sets of training data respectively being within a predefined threshold value, countermeasures may be displayed selectively.

With this mapping processing, it is possible to display an output in such a way that the coordinates of positions of the group including the training data are identifiable by any presentation method. In consequence, the user can visually decide where a noise with a feature to be detected is located on a circuit board.

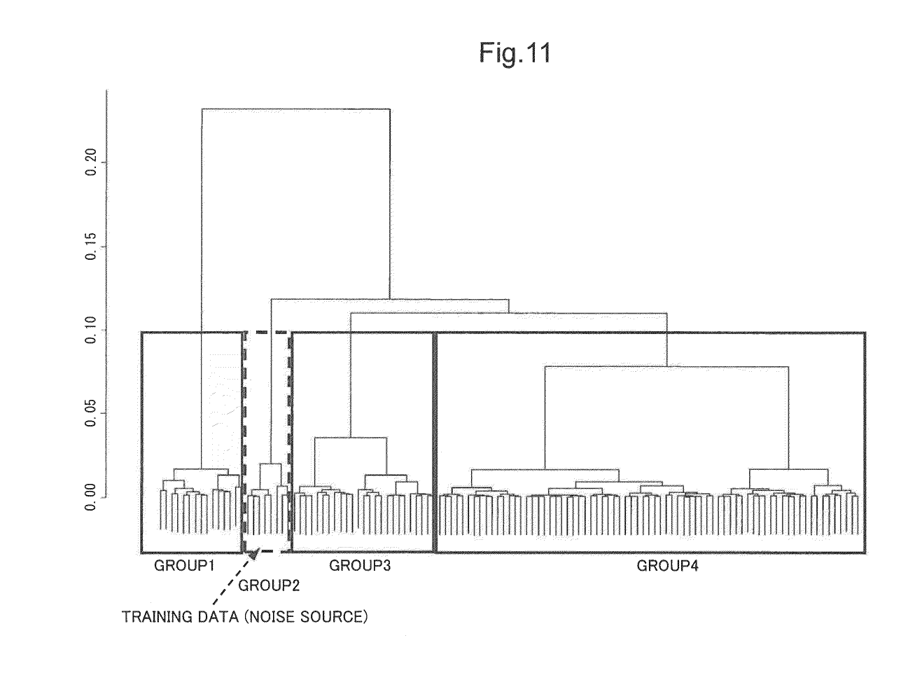

FIG. 11 is a schematic view illustrating a feature classification result including training data with which the words “noise source” are associated as an index when the whole data are divided into four groups.

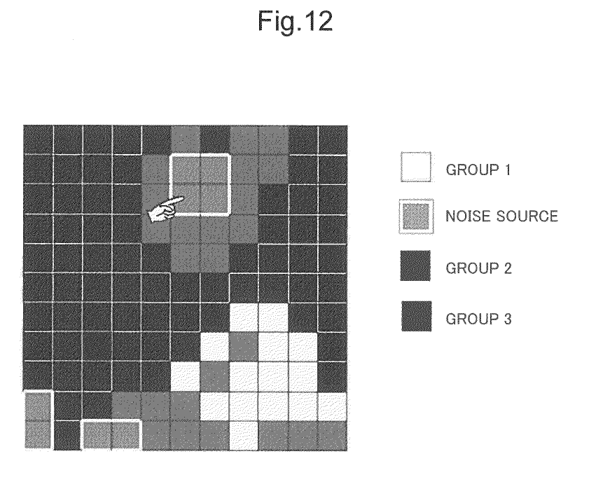

FIG. 12 is a display example of a mapping result which reflects the above-described feature classification result. By supplying a feature of a noise produced by a digital circuit A as training data, a noise source (at the lower left in FIG. 12) the feature of which resembles the feature of the above-described digital circuit A is identified in mapping the classification result.

In FIG. 12, a presentation method in which an index associated with the training data is displayed as group identification words and measurement data included in the groups in which the training data is to be included are highlighted by a closed curve encircling the measurement data is illustrated.

With this configuration, it becomes possible to automatically identify various expected noise components in accordance with features thereof by supplying a lot of training data. It is possible to make the system learn to be more highly functional as more training data are accumulated through measurement or the like. It is also possible to obtain more desirable knowledge by associating relevant training data.

### Fourth Exemplary Embodiment

As a fourth exemplary embodiment of the present invention, an electromagnetic field feature classification and presentation device that is suitable for an electromagnetic near-field distribution measurement system having a function to classify and display features of an electromagnetic wave will be described below.

The fourth exemplary embodiment has a configuration such that design data including an arrangement, a circuit board layout, an inner layer layout, or the like of an electronic circuit, which is an object to be measured, are pre-stored and used. Only an image of the object to be measured may also be used.

The electromagnetic field feature classification and presentation device of the fourth exemplary embodiment provides a function to identify arbitrarily specified coordinate positions, predetermined positions in the design data or the image, devices, circuits, or the like and stress groups into which the coordinates of positions thereof are classified.

Operations from the measurement start to the processing by a feature analysis unit 104 are the same as the operations in the first exemplary embodiment, therefore description thereof will be omitted.

In this exemplary embodiment, design information of a circuit board (circuit board layout, components placement information, or the like) is pre-stored in a storage unit 103 as the design data. Information of the coordinates of measurement points and the above-described component position information are associated with each other. The association may be carried out by hand or by referring to image recognition data, CAD data, or the like.

A mapping processing unit 105 reads in a cluster analysis result from the storage unit 103, receives a specification of the number of partitions, and selects presentation methods to be assigned to respective partitioned clusters. In this processing, the mapping processing unit 105 receives a specification of a design or an image, recognizes specified points, and, with respect to the coordinates of positions in the groups including the points, determines presentation methods by carrying out stressed display, assignment of a predetermined display colors or patterns, display of the information associated with the design data, or the like in such a way that clusters are distinguishable as required.

It is preferable that, in the selection of the coordinates of predetermined positions or the like, the user or the system is able to select desirable points at an arbitrary timing and the selection has real time characteristics.

The mapping processing unit 105 maps a feature classification result in accordance with the predetermined or arbitrary value of the number of partitions to the coordinates of respective positions on a space by applying the determined presentation methods.

As described above, selecting required data in the design data and required coordinates in the image makes it possible to perform a selection of important devices (more specifically, terminals are selectable) and the coordinates of important measurement points and identify the coordinates of positions classified by feature (classified into a cluster) into the same group as the specified devices and the coordinates of specified measurement points. It is also possible to obtain useful knowledge by a mechanism to stress selected groups on an already-presented feature classification map.

As a result, it becomes possible to use a differentiable presentation method, such as stressing the coordinates of positions classified in the same group as the coordinates of specified positions or the like, for the mapping processing which reflects the number of feature classifications, and, thus, display measurement data with similar features in a distinguishable manner based on an arbitrary specification.

Therefore, for example, the user is able to visually understand where a noise source with a feature to be identified is placed on the circuit board and which portion the noise source affects. It is also possible to obtain knowledge that can be fed back to circuit design and circuit placement.

The above-described circuit board layout may be displayed on a display in a superposed manner by associating the circuit board layout with the coordinates of measurement points. FIG. 12 is a display example of the above-described mapping result.

By visually confirming the figure, the user can identify noise sources which are the same type as a digital circuit A and a digital circuit B, both of which are important components, respectively, by referring to the design data or the image. With this configuration, it is possible to, for example, objectively decide which portion a noise produced by each component interferes with, or the like.

The above-described exemplary embodiments may be employed in combination as required. It is preferable that an intensity distribution can be displayed with the above-described display images. A feature classification distribution and an intensity distribution may be configured to be presented together in a superposed manner.

Each component in the electromagnetic field feature classification and presentation device may be implemented by using a combination of hardware and software. In an embodiment implemented by combining hardware and software, a control program used for the feature classification of an electromagnetic field is loaded on a RAM, and components are implemented as various execution means by operating the hardware, such as a control unit (CPU), based on the program. The above-described program may be distributed by being recorded in a storage medium permanently. The program recorded in the recording medium is read in to a memory via wired communication, wireless communication, or the recording medium itself and makes a control unit or the like work. The recording medium may be exemplified by an optical disk, a magnetic disk, a semiconductor memory device, a hard disk, or the like.

If the above-described exemplary embodiments are described in another expression, it can be said that it is possible to implement an information processing system that is operated as an electromagnetic field feature classification and presentation device by making a control unit function as an acquisition means, a feature amount calculation means, a feature analysis means, a mapping processing means, and so on based on an electromagnetic field feature classification program which is loaded on a RAM.

The system may be constructed on a personal computer alone, on a server, or on a cloud.

By the matters described above, it becomes possible for the electromagnetic field feature classification and presentation device to, for time series measurement data acquired with respect to the coordinates of each position, identify the coordinates of measurement points with similar features and partition the data into the required number of groups.

When distances for a plurality of sets of data in merging clusters are identical, it may be impossible to display partitioned data depending on the specified number of partitioned clusters. In this case, the system may output an alert or an error.

As described above, the electromagnetic field feature classification and presentation device and the electromagnetic near-field distribution measurement system to which the present invention is applied automatically classify features of a noise measured at the coordinates of respective measurement points by cluster analysis, and carry out mapping processing to a result of the classification by associating the coordinates of positions with the feature classifications. It is possible to decide that the coordinates of positions of the measurement data that are classified into the same group by cluster analysis have similar noise characteristics.

For example, even in a case in which a plurality of interfered portions and noise sources exist on the circuit board, it is possible to obtain knowledge of noise characteristics quickly by visually confirming the mapping result, or the like.

The feature classification method is a machine learning method by use of cluster analysis. Therefore, the feature classification method has an advantage of being difficult to be affected by an ability difference between users.

It also becomes possible to make a connection with past knowledge and countermeasures and measurement data of electromagnetic waves in a plurality of measurement directions easily. The measurement data in a plurality of measurement directions may be measured in a single scan or in a plurality of measurements. The measurement may also be carried out in three dimensions. The measurements may be carried out for the same coordinate from different angles. It is possible to obtain useful information from the measurement data with respect to the coordinates of each position by extracting a required amount of measurement data and perform cluster analysis after calculation of feature amounts at various positions and, then, applying mapping processing to the analysis result in accordance with the measurement directions or the like.

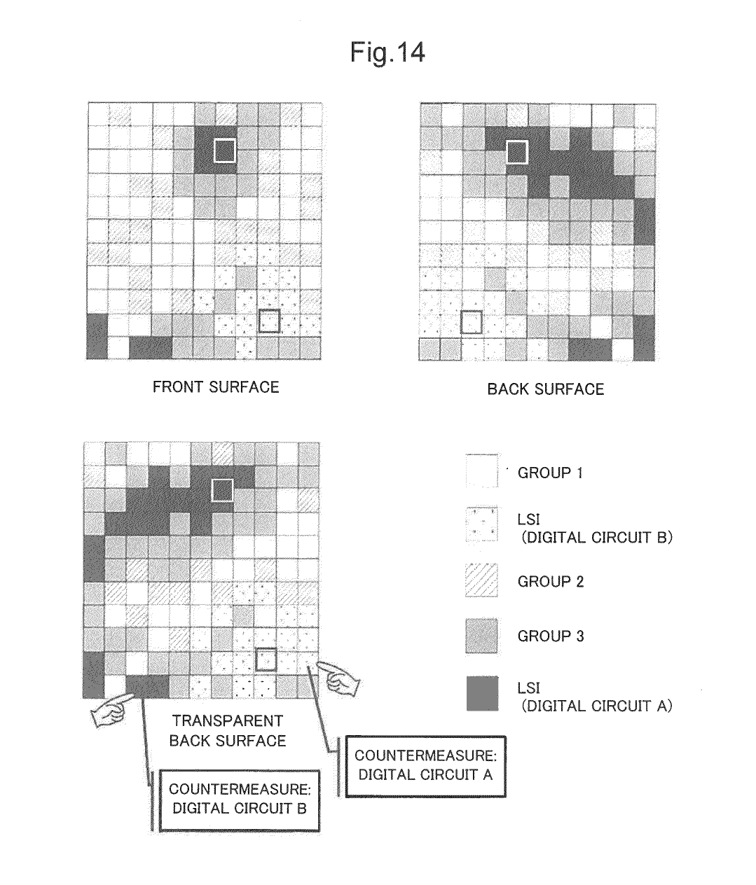

For example, a processing routine that obtains feature classifications by merging measurement data for individual surfaces of a double-sided circuit board in the feature classification and perform cluster analysis, and, then, carries out mapping processing with respect to each surface in the mapping processing may be employed. The mapping processing result may, for example, be displayed in such a way that an observed surface of the circuit board is viewed through the transparent back surface or in a mirror-reversed image as illustrated in FIG. 14. A mounting layout may also be presented in a superposed manner. In FIG. 14, indexes corresponding to the positions pointed by the cursor are presented.

In this way, it may be possible to obtain knowledge to perceive influence on other aspects. It also becomes possible to call up an inner layer pattern, via positions, or the like of a circuit board from design data easily.

As a consequence, it becomes possible to obtain measures to identify a noise source and/or a noise propagation path and to improve performance efficiently.

In other words, according to the present invention, it is possible to provide an electromagnetic field feature classification and presentation device including an electromagnetic wave feature classification function by which feature classification of electromagnetic waves emitted from an object to be measured can be carried out.

According to the present invention, it is possible to provide an electromagnetic near-field distribution measurement system for an electromagnetic near-field including an electromagnetic wave classification and presentation function which is capable of feature classification of electromagnetic waves emitted from an object to be measured.

Although exemplary embodiments of the present invention have been described above, various changes, such as separation or merger of the block configuration, exchange of procedures, and combination of individual exemplary embodiments can be applied without limitation if the effects of the present invention and the described functions are achieved, and the above description does not limit the present invention.

In the above description, it is described that measurement of time series measurement data in the acquisition unit is carried out through a measurement of an electrical field and a magnetic field. However, time series data of both an electrical field and a magnetic field may be acquired.

Description is made by using an example case in which hierarchical cluster analysis is performed. However, a non-hierarchical cluster analysis, such as k-means method, may also be performed. In this case, the user may input a desired value of the number of partitioned clusters before the execution of cluster analysis by the feature analysis unit, and, then, the non-hierarchical cluster analysis may be carried out based on the number of partitions.

Although a classification result is mapped to lattice-shaped blocks as an example of mapping in the mapping processing unit, without limited to the shape, rectangles, hexagons, or circles, which reflect a detection range of a probe, may be used in the mapping.

In the presentation, the coordinates of positions in the same group may be associated by curves in the form of contour.

All or part of the embodiments described above may be described as the followings. The following supplementary notes do not limit the present invention in any way.

### [Supplementary Note 1]

An electromagnetic field feature classification and presentation device, including:

an acquisition means for collecting time series measurement data on an electromagnetic wave emitted from an object to be measured in association with each coordinate of position;

a feature amount calculation means for calculating one or a plurality of feature amounts for each coordinate of position with respect to the measurement data collected by the acquisition means;

a feature analysis means for performing feature classification based on a cluster analysis for a group of the feature amounts calculated by the feature amount calculation means at each coordinate of position;

a mapping processing means for associating classification result by the feature analysis means with the coordinate of position and maps the classification result on a space corresponding to the object to be measured by applying the number of feature classifications; and

an output means for presenting a result of mapping by the mapping processing means.

### [Supplementary Note 2]

The electromagnetic field feature classification and presentation device according to Supplementary note described above,

wherein the mapping processing means reads in cluster distances produced between respective clusters from a result of cluster analysis by the feature analysis means and distinguishes presentation methods to be assigned to respective clusters in performing presentation based on values of the cluster distances.

### [Supplementary Note 3]

The electromagnetic field feature classification and presentation device according to Supplementary note described above, wherein

time series samples reflecting features relating to the electromagnetic wave to be classified as training data is stored and held in a storage unit in advance,

the feature analysis means carries out feature classification based on the cluster analysis for group of the feature amounts calculated by the feature amount calculation means at each coordinate of position and the training data, and

when the mapping processing means associates the classification result by the feature analysis means with the coordinate of position and maps the classification result to the space corresponding to the object to be measured, the mapping processing means carries out mapping processing in such a way that the coordinates of position of measurement data clustered into the same group as the training data is identifiable.

### [Supplementary Note 4]

The electromagnetic field feature classification and presentation device according to Supplementary note described above,

wherein an index to be presented to a user is associated with the training data, and

the electromagnetic field feature classification and presentation device carries out mapping processing for the coordinate of position of measurement data clustered into the same group as the training data in such a way that the index associated with the training data is distinguishable.

### [Supplementary Note 5]

The electromagnetic field feature classification and presentation device according to Supplementary note described above,

wherein, when the mapping processing means associates the classification result by the feature analysis means with the coordinate of position and maps the classification result on the space corresponding to the object to be measured, the mapping processing means carries out mapping processing in such a way that the coordinates of position of measurement data clustered into the same group as an arbitrarily designated coordinate position is distinguishable.

### [Supplementary Note 6]

The electromagnetic field feature classification and presentation device according to Supplementary note described above, wherein

design data relating to the object to be measured, which is to be analyzed, is stored and held in the storage unit in advance, and

when the mapping processing means associates the classification results by the feature analysis means with the coordinates of positions and maps the classification result on the space corresponding to the object to be measured, the mapping processing means carries out mapping processing in such a way that the coordinates of positions of measurement data clustered into the same group as a coordinate position designated on the design data is distinguishable.

### [Supplementary Note 7]

The electromagnetic field feature classification and presentation device according to Supplementary note described above, wherein

an image relating to the object to be measured, which is to be analyzed, is stored and held in the storage unit in advance, and

when the mapping processing means associates the classification results by the feature analysis means with the coordinate of position and maps the classification result on the space corresponding to the object to be measured, the mapping processing means carries out mapping processing in such a way that the coordinate of position of measurement data clustered into the same group as a coordinate position designated on the image is distinguishable.

### [Supplementary Note 8]

The electromagnetic field feature classification and presentation device according to Supplementary note described above,

wherein time series measurement data collected by the acquisition means include measurement data individually collected from a plurality of measurement directions with respect to the object to be measured,

the feature analysis means carries out feature classification based on the cluster analysis for the group of feature amounts at each coordinate of position relating to measurement data collected from a plurality of required measurement directions, and

the mapping processing means associates the classification result by the feature analysis means with the coordinate of position and maps the classification result on a space corresponding to each of the plurality of required measurement directions with respect to the object to be measured by applying the number of feature classifications.

### [Supplementary Note 9]

The electromagnetic field feature classification and presentation device according to Supplementary note described above,

wherein time series measurement data collected by the acquisition means include measurement data individually collected from both faces with respect to the object to be measured, which is in the form of a plate,

the feature analysis means carries out feature classification based on the cluster analysis for the group of feature amounts at each coordinate of position relating to the measurement data collected from both faces, and

the mapping processing means associates the classification result by the feature analysis means with the coordinate of position and maps the classification result on a space corresponding to each face of the object to be measured by applying the number of feature classifications.

### [Supplementary Note 10]

An electromagnetic near-field distribution measurement system, including:

a probe that senses an electromagnetic near field;

a probe scanning means fort scanning the probe;

a control means for controlling the probe scanning means in synchronization with measurement of an electromagnetic wave(s);

an acquisition means for collecting time series measurement data on an electromagnetic wave emitted from an object to be measured via the probe in association with each coordinate of position;

a feature amount calculation means for calculating one or a plurality of feature amounts for each coordinate of position with respect to the measurement data collected by the acquisition means;

a feature analysis means for performing feature classification based on a cluster analysis for a group of the feature amounts calculated by the feature amount calculation means at each coordinate of position;

a mapping processing means for associating classification result by the feature analysis means with the coordinate of position and maps the classification result on a space corresponding to the object to be measured by applying the number of feature classifications; and

an output means for presenting a result of mapping by the mapping processing means.

### [Supplementary Note 11]

An electromagnetic near-field distribution measurement system including the electromagnetic field feature classification and presentation device according to Supplementary note described above.

### [Supplementary Note 12]

An electromagnetic near-field distribution measurement system according to Supplementary note described above,

wherein the control means controls the probe scanning means in synchronization with measurement of an electromagnetic wave so as to change a position, an angle, or a face of the object to be measured in accordance with probe operations.

### [Supplementary Note 13]

An electromagnetic near-field distribution measurement system according to Supplementary note described above,

wherein the control means controls the object to be measured in synchronization with measurement of an electromagnetic wave so that the object to be measured performs a required movement at a required timing.

### [Supplementary Note 14]

An electromagnetic field feature classification program that causes a control unit of an information processing system to function as:

an acquisition means for collecting time series measurement data on an electromagnetic wave emitted from an object to be measured in association with each coordinate of position;

a feature amount calculation means for calculating one or a plurality of feature amounts for each coordinate of position with respect to t the measurement data collected by the acquisition means;

a feature analysis means for performing feature classification based on a cluster analysis for a group of the feature amounts calculated by the feature amount calculation means at each coordinate of position; and

a mapping processing means for associating classification results by the feature analysis means with the coordinates of positions and maps the classification result on a space corresponding to the object to be measured by applying the number of feature classifications.

### [Supplementary Note 15]

An electromagnetic field feature classification program that is constructed so as to implement the electromagnetic field feature classification and presentation device according to Supplementary notes described above.

### [Supplementary Note 16]

An electromagnetic field feature classification program according to Supplementary note described above, further causing a control unit of an information processing system to function as

a control means for controlling a probe scanning means to scan a probe that senses an electromagnetic near field in synchronization with measurement of an electromagnetic wave.

### [Supplementary Note 17]

An electromagnetic field feature classification program according to Supplementary note described above,

wherein the program causes the control means to operate the probe scanning means in synchronization with measurement of an electromagnetic wave so as to change a position, an angle, or a face of the object to be measured in accordance with probe operations.

### [Supplementary Note 18]

An electromagnetic field feature classification program according to Supplementary note described above,

wherein the program causes the control means to operate the object to be measured in synchronization with measurement of an electromagnetic wave so that the object to be measured performs a required movement at a required timing.

### [Supplementary Note 19]

An electromagnetic field feature classification method, including:

collecting time series measurement data on an electromagnetic wave emitted from an object to be measured in association with each coordinate of position;

calculating one or a plurality of feature amounts with respect to each coordinate of position for the collected measurement data;

performing feature classification processing based on cluster analysis for a group of the calculated feature amounts at each coordinate of position; and

associating classification result by the feature classification processing with the coordinates of positions and mapping the classification results on a space corresponding to the object to be measured by applying the number of feature classifications.

### [Supplementary Note 20]

The electromagnetic field feature classification method according to Supplementary note described above,

wherein the mapping processing reads in cluster distances produced between respective clusters from a result of cluster analysis by feature analysis and distinguishes presentation methods to be assigned to respective clusters in a presentation based on values of the cluster distances.

### [Supplementary Note 21]

The electromagnetic field feature classification method according to Supplementary note described above,

wherein time series samples which reflect features of an electromagnetic wave to be classified are stored and held as training data in advance,

in the feature analysis, feature classification based on the cluster analysis is carried out to the group of calculated feature amounts at each coordinate of positions and the training data, and

in the mapping processing, when classification result are associated with the coordinate of position and mapped on the space corresponding to the object to be measured, the classification results are mapped in such a way that the coordinate of position of measurement data clustered into the same group as the training data is distinguishable.

### [Supplementary Note 22]

A electromagnetic field feature classification method according to Supplementary note described above,

wherein an index to be presented to a user is associated with the training data, and

the coordinate of position of measurement data clustered into the same group as the training data is mapped in such a way that the index associated with the training data is distinguishable.

### [Supplementary Note 23]

The electromagnetic field feature classification method according to Supplementary note described above,

wherein, in the mapping processing, when classification results are associated with the coordinate of position and mapped on the space corresponding to the object to be measured, the classification result are mapped in such a way that the coordinate of position of measurement data clustered into the same group as an arbitrarily designated coordinate position is distinguishable.

### [Supplementary Note 24]

The electromagnetic field feature classification method according to Supplementary note described above,

wherein design data relating to an object to be measured, which is to be analyzed, are stored and held in advance, and

in the mapping processing, when the classification result are associated with the coordinate of position and mapped on the space corresponding to the object to be measured, the classification result are mapped in such a way that the coordinate of position of measurement data clustered into the same group as a designated coordinate position in the design data is distinguishable.

### [Supplementary Note 25]

The electromagnetic field feature classification method according to Supplementary note described above,

wherein an image of an object to be measured, which is to be analyzed, is stored and held in advance, and

in the mapping processing, when the classification result are associated with the coordinate of position and mapped on the space corresponding to the object to be measured, the classification result is mapped in such a way that the coordinate of position of measurement data clustered into the same group as a designated coordinate position on the image is distinguishable.

### [Supplementary Note 26]

The electromagnetic field feature classification method according to Supplementary note described above,

wherein collected time series measurement data include measurement data collected from each of a plurality of measurement directions with respect to the object to be measured,

in the feature analysis, feature classification based on the cluster analysis is carried out for the group of feature amounts at each coordinate of position of the measurement data collected from a plurality of required measurement directions, and

in the mapping processing, classification results are associated with the coordinate of position and mapped on a space corresponding to each of the required plurality of measurement directions of the object to be measured by applying the number of feature classifications.

### [Supplementary Note 27]

The electromagnetic field feature classification method according to Supplementary note described above,

wherein collected time series measurement data include measurement data collected from each of both faces with respect to the object to be measured, which is in the form of a plate,

in the feature analysis, feature classification based on the cluster analysis is carried out for the group of feature amounts at each coordinate of position of the measurement data collected from both faces, and

in the mapping processing, classification results are associated with the coordinate of position and mapped on a space corresponding to each face of the object to be measured by reflecting the number of feature classifications.

### INDUSTRIAL APPLICABILITY

By using the electromagnetic field feature classification method, it is possible to obtain knowledge to apply EMI countermeasures effectively. It is also possible to obtain knowledge useful for an improvement in emission characteristics of antennas or the like. The electromagnetic field feature classification method can also be used for tracking a predetermined signal line.

This application is based on Japanese Patent Application No. 2012-234641, filed in Japanese Patent Office on Oct. 24, 2012, the disclosure of which is incorporated herein in its entirety by reference.

1. An electromagnetic field feature classification and presentation device, comprising:
an acquisition means for collecting unit that collects time series measurement data on an electromagnetic wave emitted from an object to be measured in association with each coordinate of position;
a feature amount calculation means for calculating unit that calculates one or a plurality of feature amounts for each coordinate of position with respect to the measurement data collected by the acquisition means unit;
a feature analysis means for performing unit that performs feature classification based on a cluster analysis for a group of the feature amounts calculated by the feature amount calculation means unit at each coordinate of position;
a mapping processing means for associating unit that associates a classification result by the feature analysis means unit with the coordinate of position and maps the classification result on a space corresponding to the object to be measured by applying the number of feature classifications; and
an output means for presenting unit that presents a result of mapping by the mapping processing means unit.

2. The electromagnetic field feature classification and presentation device according to claim 1, wherein
the mapping processing means unit reads in cluster distances produced between respective clusters from a result of cluster analysis by the feature analysis means unit, and distinguishes presentation methods to be assigned to respective clusters in a presentation based on values of the cluster distances.

3. The electromagnetic field feature classification and presentation device according to claim 1, wherein
time series samples which reflect features of an electromagnetic wave to be classified as training data is stored and held in a storage unit in advance,
the feature analysis means unit performs feature classification based on the cluster analysis for the group of the feature amounts calculated by the feature amount calculation means unit at each coordinate of position and the training data, and
when the mapping processing means unit associates the classification result by the feature analysis means unit with the coordinate of position and maps the classification result on the space corresponding to the object to be measured, the mapping processing means unit performs mapping processing in such a way that the coordinate of position of measurement data clustered into the same group as the training data is distinguishable.

4. The electromagnetic field feature classification and presentation device according to claim 3, wherein
an index to be presented to a user is associated with the training data, and
the coordinate of position of measurement data clustered into the same group as the training data is mapped in such a way that the index associated with the training data is distinguishable.

5. The electromagnetic field feature classification and presentation device according to claim 1, wherein
when the mapping processing means unit associates the classification result by the feature analysis means unit with the coordinate of position and maps the classification result on the space corresponding to the object to be measured, the mapping processing means unit performs mapping processing in such a way that the coordinate of position of measurement data clustered into the same group as an arbitrarily designated coordinate position is distinguishable.

6. The electromagnetic field feature classification and presentation device according to claim 5, wherein
design data of an object to be measured, which is to be analyzed, is stored and held in a storage unit in advance, and
when the mapping processing means unit associates the classification result by the feature analysis means unit with the coordinate of position and maps the classification result on the space corresponding to the object to be measured, the mapping processing means unit performs mapping processing in such a way that the coordinate of position of measurement data clustered into the same group as a designated coordinate position in the design data is distinguishable.

7. The electromagnetic field feature classification and presentation device according to claim 5, wherein,
an image of an object to be measured, which is to be analyzed, is stored and held in a storage unit in advance, and
when the mapping processing means unit associates the classification result by the feature analysis means unit with the coordinate of position and maps the classification result on the space corresponding to the object to be measured, the mapping processing means unit performs mapping processing in such a way that the coordinate of position of measurement data clustered into the same group as a designated coordinate position on the image is distinguishable.

8. An electromagnetic near-field distribution measurement system, comprising:
a probe that senses an electromagnetic near field;
a probe scanning means for scanning unit that scans the probe;
a control means for controlling unit that controls the probe scanning means unit in synchronization with measurement of an electromagnetic wave;
an acquisition means for collecting unit that collects time series measurement data on an electromagnetic wave emitted from an object to be measured via the probe in association with each coordinate of position;
a feature amount calculation means for calculating unit that calculates one or a plurality of feature amounts for each coordinate of position with respect to the measurement data collected by the acquisition means unit;
a feature analysis means for performing unit that performs feature classification based on a cluster analysis for a group of the feature amounts calculated by the feature amount calculation means unit at each coordinate of position;
a mapping processing means for associating unit that associates a classification result by the feature analysis means unit with the coordinate of position and maps the classification result on a space corresponding to the object to be measured by applying the number of feature classifications; and
an output means for presenting unit that presents a result of mapping by the mapping processing means unit.

9. An electromagnetic field feature classification program that causes a control unit of an information processing system to function as:
an acquisition means for collecting unit that collects time series measurement data on an electromagnetic wave emitted from an object to be measured in association with each coordinate of position;
a feature amount calculation means for calculating unit that calculates one or a plurality of feature amounts for each coordinate of position with respect to the measurement data collected by the acquisition means unit;
a feature analysis means for performing unit that performs feature classification based on a cluster analysis for a group of the feature amounts calculated by the feature amount calculation means unit at each coordinate of position; and
a mapping processing means for associating unit that associates a classification result by the feature analysis means unit with the coordinates of positions and maps the classification result on a space corresponding to the object to be measured by reflecting the number of feature classifications.

10. An electromagnetic field feature classification method, comprising:
collecting time series measurement data on an electromagnetic wave emitted from an object to be measured in association with each coordinate of position;
calculating one or a plurality of feature amounts for each coordinate of position with respect to the collected measurement data;
performing feature classification processing based on a cluster analysis for a group of the calculated feature amounts at the each coordinate of position; and
associating a classification result by the feature classification processing with the coordinates of positions and mapping the classification results on a space corresponding to the object to be measured by reflecting the number of feature classifications.
